(19) United States
(12) Patent Application Publication
(10) Pub. No.: US 2026/0110093 A1
(43) Pub. Date: Apr. 23, 2026

(54) Substrate Processing Apparatus, Substrate Processing Method, Method of Manufacturing Semiconductor Device and Non-transitory Computer-readable Recording Medium

(71) Applicant: Kokusai Electric Corporation, Tokyo (JP)

(72) Inventors: Shinsuke KUBOTA, Toyama (JP); Shunsuke NAKATANI, Toyama (JP); Takuya KATO, Toyama (JP)

(21) Appl. No.: 19/340,984

(22) Filed: Sep. 26, 2025

(30) Foreign Application Priority Data
Oct. 18, 2024 (JP) 2024-183594

(51) Int. Cl. C23C 16/52; C23C 16/455; H01L 21/02

(52) U.S. Cl. CPC C23C 16/52; C23C 16/45561; H10P 14/6334

(57) ABSTRACT

It is possible to improve a productivity of substrate processing. There is provided a technique that includes: a process chamber; a source material supplier provided with containers storing the source material and capable of being replaced; a determination processor configured to check a remaining amount of the source material in a container currently in use among the containers during a substrate processing, and further configured to determine, from the remaining amount, whether or not a supply source of the source material needs to be switched from the container currently in use to a container in standby among the containers; and a controller configured to be capable of controlling the supply of the source material to be continuously performed by switching the container currently in use to the container in standby based on a determination result obtained by the determination processor.

### CROSS REFERENCE TO RELATED APPLICATIONS

This non-provisional U.S. patent application is based on and claims priority under 35 U.S.C. § 119(a)-(d) to Japanese Patent Application No. 2024-183594, filed on Oct. 18, 2024, in the Japanese Patent Office, the entire contents of which are hereby incorporated by reference.

### TECHNICAL FIELD

The present disclosure relates to a substrate processing apparatus, a substrate processing method, a method of manufacturing a semiconductor device and a non-transitory computer-readable recording medium.

### BACKGROUND

When forming a film on a surface of a semiconductor wafer, a substrate processing apparatus including a reactor provided with a wafer placement structure in an inside (inner portion) thereof may be used. A pipe through which a gas such as a source gas is introduced is connected to the reactor, and the source gas is introduced into the reactor through the pipe from a source material supply tank capable of storing a source material of the source gas.

Conventionally, when a substance in a solid state at a room temperature (that is, a solid substance such as AlCl₃) is used as the source material for forming the film using the substrate processing apparatus and the substance is supplied to the reactor from an outside (outer portion) of the reactor, a tank serving as a container capable of storing the source material in a solid state is provided, and the source material is sublimated in the tank and supplied to the reactor as the source gas through the pipe. However, when the source material is in the solid state, it may not be possible to replenish (or refill) the source material in the source material supply tank.

Therefore, when the solid source material in the source material supply tank runs out, the source material supply tank in an empty state is removed from the substrate processing apparatus and replaced with another source material supply tank which is sufficiently filled with the source material in the solid state. According to some related arts, the substrate processing apparatus capable of forming the film on the surface of the wafer by supplying the source gas to the reactor from the outside of the reactor is disclosed.

However, conventionally, the source material supply tank can be replaced only when an execution of a process recipe in a substrate processing is stopped. Therefore, there is room for improvement.

### SUMMARY

According to the present disclosure, there is provided a technique capable of improving a productivity of a substrate processing.

According to an embodiment of the present disclosure, there is provided a technique that includes: a process chamber in which a substrate is processed; a source material supplier configured to supply a source material to the process chamber and provided with a plurality of containers, wherein the plurality of containers are configured to store the source material and configured to be capable of being replaced; a determination processor configured to check a remaining amount of the source material in a container currently in use among the plurality of containers during a substrate processing, and further configured to determine, from the remaining amount, whether or not a supply source of the source material needs to be switched from the container currently in use to a container in standby among the plurality of containers; and a controller configured to be capable of controlling the supply of the source material to be continuously performed by switching the container currently in use to the container in standby based on a determination result obtained by the determination processor.

### BRIEF DESCRIPTION OF THE DRAWINGS

FIG. 1 is a diagram schematically illustrating a vertical cross-section of a vertical type process furnace in a substrate processing apparatus according to one or more embodiments of the present disclosure.

FIG. 2 is a block diagram schematically illustrating a configuration of a controller and its related components of the substrate processing apparatus according to the embodiments of the present disclosure.

FIG. 3 is a flow chart schematically illustrating a substrate processing according to the embodiments of the present disclosure.

### DETAILED DESCRIPTION

### Structure of Substrate Processing Apparatus

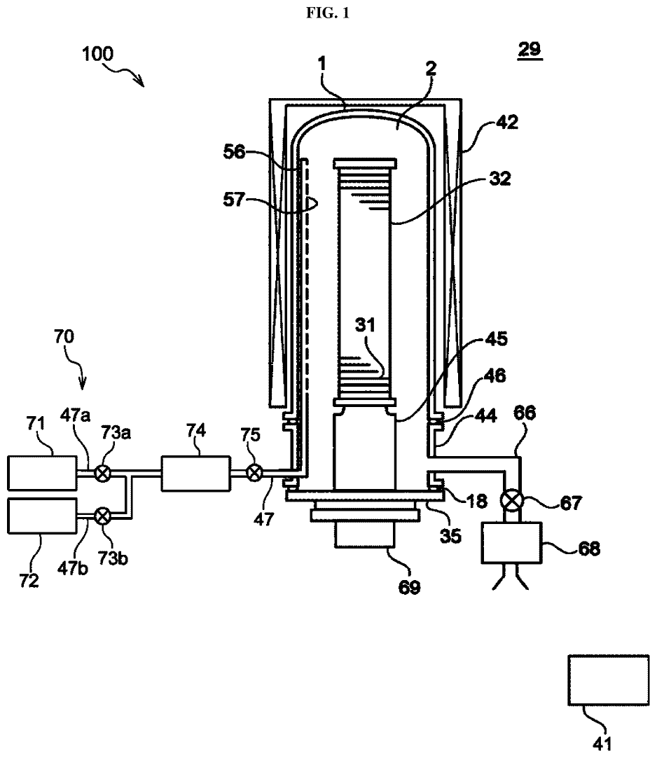

FIG. 1 is a diagram schematically illustrating a vertical type process furnace (hereinafter, also simply referred to as a “process furnace”) 29 used in a substrate processing apparatus 100 serving as an example of a processing apparatus to which the technique of the present disclosure is applied. The substrate processing apparatus 100 includes a process chamber 2, a source material supplier (which is a source material supply structure or a source material supply system) 70, a determination processor 50 and a controller 41 serving as an example of a control structure. First, an outline of an operation of the substrate processing apparatus 100 to which the technique of the present disclosure is applied will be described with reference to FIG. 1. For example, the drawings used in the following descriptions are all schematic, and a relationship between dimensions of each component and a ratio of each component shown in the drawing may not always match the actual ones. In addition, even between the drawings, the relationship between the dimensions of each component and the ratio of each component may not always match.

When a predetermined number of wafers 31 serving as substrates are transferred and charged (or loaded) into a boat 32 serving as a holder (retainer), the boat 32 is elevated by a boat elevator (not shown). Thereby, the boat 32 is loaded into the process furnace 29. Hereinafter, each of the wafers 31 may also be referred to as a “wafer 31”. With the boat 32 completely loaded, the process furnace 29 is airtightly closed by a seal cap 35. In the process furnace 29 airtightly closed, in accordance with a process recipe appropriately selected, the wafer 31 is heated and a process gas (for example, a source gas) is supplied into the process furnace 29. Thereby, the wafer 31 is processed while an atmosphere (inner atmosphere) of the process chamber 2 is exhausted through a gas exhaust pipe 66 by an exhaust apparatus. The process chamber 2 serves as a space in which the wafers 31 are processed.

Subsequently, the process furnace 29 will be described with reference to FIG. 1. A reaction tube 1 is provided in an inner side of a heater 42 serving as a heating apparatus (heating structure). A manifold 44 is connected to a lower end of the reaction tube 1 through an O-ring 46 serving as an airtight seal. For example, the manifold 44 is made of a material such as stainless steel. A lower end opening (also referred to as a “furnace opening”) of the manifold 44 is airtightly closed by the seal cap 35 serving as a lid through an O-ring 18 serving as an airtight seal. The process chamber 2 is defined by at least the reaction tube 1, the manifold 44 and the seal cap 35.

The boat 32 is supported on the seal cap 35 through a boat support (which is a boat supporting structure) 45. The boat support 45 serves as a holder capable of holding (or supporting) the boat 32.

The source material supplier 70 includes tanks (for example, a first tank 71 and a second tank 72) serving as exchangeable containers in which a source material of the source gas is stored, and configured to supply the source material (that is, the source material vaporized as described later) to the process chamber 2. For example, a supply pipe 47 serving as a supply path (through which the source material vaporized as described later is supplied) is provided at the process chamber 2. At a front end (tip) of the supply pipe 47, a nozzle 56 is provided. The nozzle 56 extends from a lower portion to an upper portion of the reaction tube 1 along an inner wall of the reaction tube 1. A plurality of supply holes 57 through which the source gas is supplied are provided on a side surface of the nozzle 56. The supply holes 57 are provided from a lower portion to an upper portion of the nozzle 56 such that each of the supply holes 57 is provided at the same pitch and an opening area of each of the supply holes 57 is the same.

An upstream side of the supply pipe 47 branches into supply pipes 47a and 47b. The first tank 71 is detachably connected to the supply pipe 47a, and the second tank 72 is detachably connected to the supply pipe 47b. The supply pipe 47 between the source material supplier 70 and the process chamber 2 is provided with valves 73a and 73b respectively configured to perform a supply of the source material and stop the supply of the source material from the first tank 71 and the second tank 72 to the process chamber 2. The first tank 71 and the second tank 72 are provided in parallel with each other, and the first tank 71 and the second tank 72 can be switched by the valves 73a and 73b. Alternatively, a three-way valve may be used instead of the valves 73a and 73b.

A buffer tank 74 may be provided between the first tank 71, the second tank 72 and the process chamber 2. The buffer tank 74 serves as a storage (reservoir) for temporarily storing the source material. The buffer tank 74 is configured to be capable of supplying the source material to the process chamber 2 even while switching from a tank currently in use (for example, the first tank 71) to a tank in standby (for example, the second tank 72). A valve 75 is provided at a downstream side of the buffer tank 74 in the supply pipe 47. For example, the number of the tanks (such as the first tank 71 and the second tank 72) is not limited to two, and may be three or more. In addition, a buffer tank (such as the buffer tank 74) may be configured to be capable of supplying the source material to the process chamber 2 even while switching from the tank currently in use. As a result, it is possible to perform a substrate processing described later continuously without interruption even when switching the tanks.

The source material is heated and vaporized, and then is supplied to the process chamber 2 as the source gas. Each of the first tank 71 and the second tank 72 is provided with a vaporizer (for example, a heating structure) such that the source material can be vaporized. For example, the buffer tank 74 may be provided with a heating structure to maintain the source material in a vaporized state. Alternatively, the source material in the first tank 71 and the second tank 72 may be in a liquid state or in a gaseous state. For example, the source material in the first tank 71 and the second tank 72 may be a solid source material (that is, a source material in a solid state) containing chlorine (Cl). As the source gas, for example, a solid source material such as aluminum trichloride (AlCl₃) may be used. In addition, depending on process conditions for the substrate (the wafer 31), a solid source material such as hafnium tetrachloride (HfCl₄), molybdenum pentachloride (MoCl₅) and molybdenum dioxide dichloride (MoO₂Cl₂) may also be used.

The process chamber 2 is connected to a vacuum pump 68 serving as the exhaust apparatus (which is an exhaust structure) via the gas exhaust pipe 66 through which the gas is exhausted. As described above, the inner atmosphere of the process chamber 2 is vacuum-exhausted through the gas exhaust pipe 66 by the vacuum pump 68. A valve 67 serving as a pressure adjusting valve is configured as an opening/closing valve. That is, the valve 67 is configured to be capable of performing a vacuum exhaust of the process chamber 2 and stopping the vacuum exhaust of the process chamber 2 by opening or closing a valve structure thereof, and further configured to be capable of adjusting a pressure (inner pressure) of the process chamber 2 by adjusting an opening degree of the valve structure thereof.

A boat rotator (which is a boat rotating structure) 69 is provided at the seal cap 35, and the boat rotator 69 is configured to rotate the boat 32 to improve a uniformity of a processing such as the substrate processing.

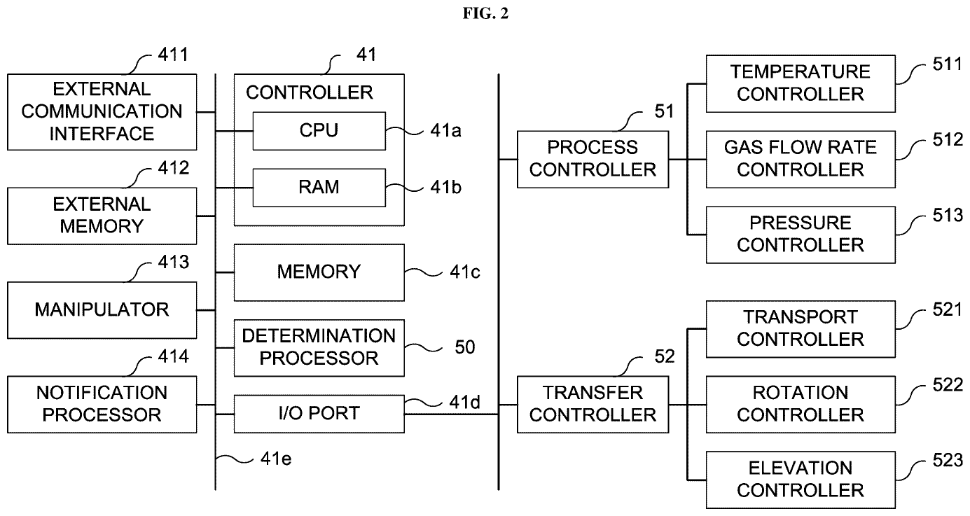

As shown in FIG. 2, the substrate processing apparatus 100 includes the controller 41 serving as a control structure configured to control operations of components constituting the substrate processing apparatus 100.

For example, the controller 41 serving as the control structure (control apparatus) includes a CPU (Central Processing Unit) 41a and a RAM (Random Access Memory) 41b. For example, the controller 41 may be constituted by a computer including the CPU 41a, the RAM 41b, a memory 41c and an I/O port (input/output port) 41d. The RAM 41b, the memory 41c and the I/O port 41d are configured to be capable of changing data with the CPU 41a through an internal bus 41e.

For example, the memory 41c is configured by a component such as a flash memory and a hard disk drive (HDD). For example, a control program configured to control the operation of the substrate processing apparatus 100, a process recipe containing information on procedures and conditions of the substrate processing described later and a correction recipe containing information on procedures and conditions of a characteristics checking step described later may be readably stored in the memory 41c. The process recipe or the correction recipe is obtained by combining steps (procedures) of the substrate processing performed in a substrate processing mode or the characteristics checking step such that the controller 41 can execute the steps to acquire a predetermined result, and functions as a program. In the present specification, the term “program” may refer to the process recipe (or the correction recipe) alone, may refer to the control program alone or may refer to both of the process recipe (or the correction recipe) and the control program. The RAM 41b functions as a memory area (work area) where a program or data read by the CPU 41a is temporarily stored.

For example, the controller 41 is configured to be capable of being connected to an external communication interface (“ECI” shown in FIG. 2) 411, an external memory 412, a manipulator 413 (which is configured as a component such as a touch panel) and a notification processor 414. The controller 41 configured to be capable of transmitting and receiving information to and from other apparatuses via the external communication interface 411 and a network. The notification processor 414 is a structure provided with a function of notifying a processing status of the wafer 31. When receiving a notification from the controller 41, the notification processor 414 issues a notification to replace the tank currently in use. The notification may be performed by a message display, a turn on of a lamp, a blinking of the lamp, a buzzer or anything else which is configured such that an operating personnel can understand. By clearly indicating an instruction to replace the tank, the operating personnel can recognize that the tank needs to be replaced. In addition, the controller 41 may further include a component such as a process controller 51 and a transfer controller 52.

For example, the I/O port 41d is connected to the process controller 51 configured to control the substrate processing, and the transfer controller 52 configured to control a transfer of the wafer 31. For example, the process controller 51 is configured to control a temperature controller 511, a gas flow rate controller 512 and a pressure controller 513. For example, the transfer controller 52 is configured to control a transport controller 521 configured to perform an operation such as a loading and an unloading of the wafer 31, a rotation controller 522 and an elevation controller 523.

For example, the controller 41 is not limited to a dedicated computer, and may be embodied by a general-purpose computer. For example, the controller 41 according to the present embodiments may be embodied by preparing the external memory 412 storing the program and by installing the program onto the general-purpose computer using the external memory 412. For example, the external memory 412 may include a semiconductor memory such as a USB memory and a memory card. However, a method of providing the program to the computer is not limited to that using the external memory 412. For example, the program may be supplied to the computer (general-purpose computer) using a communication interface such as the Internet and a dedicated line without using the external memory 412. The memory 41c or the external memory 412 may be embodied by a non-transitory computer readable recording medium. Hereafter, the memory 41c and the external memory 412 may be collectively or individually referred to as a “recording medium”. Thus, in the present specification, the term “recording medium” may refer to the memory 41c alone, may refer to the external memory 412 alone, or may refer to both of the memory 41c and the external memory 412.

The determination processor 50 is configured to check a remaining amount of the source material in the tank currently in use during the substrate processing, and is further configured to determine whether or not the supply source of the source material needs to be switched from the tank currently in use to the tank in standby based on the remaining amount.

The determination processor 50 may compare the remaining amount in the tank currently in use with a predetermined threshold value to determine whether or not the tank needs to be switched. For example, the determination processor 50 compares the remaining amount in the tank currently in use with the threshold value at intervals of 100 ms, and notifies the controller 41 of a comparison result. As a result, for example, the controller 41 can recognize a need to switch to the second tank 72 without depleting (or running out) the remaining amount in the first tank 71.

The determination processor 50 may notify the controller 41 of a determination result that the tank currently in use needs to be switched to the tank in standby when the remaining amount in the tank currently in use is less than the threshold value.

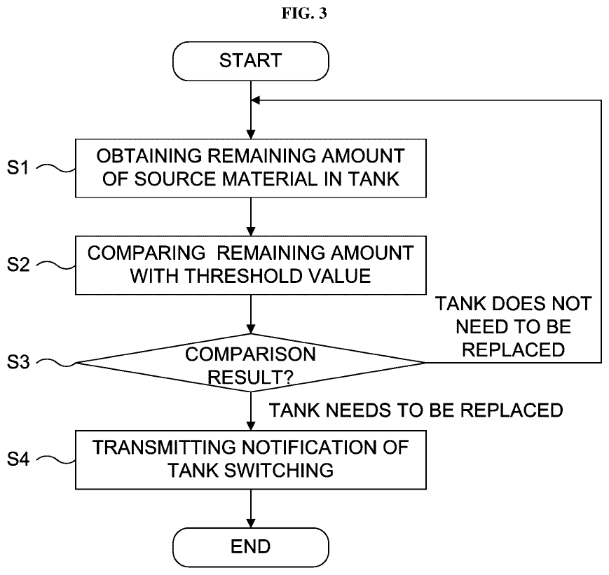

Specifically, as shown in a flow chart in FIG. 3, in a step S1, the remaining amount of the source material in the tank currently in use is obtained. In a step S2, the remaining amount in the tank is compared with the threshold value. In a step S3, when the comparison result indicates that the tank needs to be replaced (that is, switched), in a step S4, a notification requesting a tank switching is transmitted to the controller 41. In the step S3, when the comparison result indicates that the tank does not need to be replaced, the step S1 is performed again. In such a manner, when the determination processor 50 determines that the tank needs to be switched, the determination processor 50 notifies the controller 41. By sending the notification only when the tank needs to be replaced, it is possible to reduce a communication load.

When the remaining amount in the tank currently in use is greater than or equal to the threshold value, the determination processor 50 may notify the controller 41 of the determination result that the tank currently in use does not need to be switched. For example, in such a case, by sending a notification including information on the remaining amount in the tank currently in use, it is possible to clearly check the remaining amount in the tank currently in use, and it is also possible to display the remaining amount in the tank currently in use in real time, for example, by the notification processor 414.

When the remaining amount in the tank currently in use is greater than or equal to the threshold value, the determination processor 50 may not notify the controller 41 of the determination result that the tank currently in use does not need to be switched. In other words, when the determination processor 50 determines that the tank currently in use does not need to be switched, the determination processor 50 may not notify the controller 41. That is, the determination processor 50 may notify the controller 41 when the determination processor 50 determines that the tank currently in use needs to be switched. By sending the notification only when the tank currently in use needs to be switched, it is possible to reduce the communication load.

Based on the determination result by the determination processor 50, the controller 41 is configured to be capable of controlling a switching of the tank currently in use to the tank in standby and configured to be capable of continuously supplying the source material. For example, such a switching control is performed by the process controller 51 (FIG. 2). Thereby, it is possible to continuously perform the substrate processing without being stopped when switching the tanks. As a result, it is possible to improve a productivity of the substrate processing.

Based on the determination result, the controller 41 may be configured to be capable of independently controlling the valve 73a of the first tank 71 and the valve 73b of the second tank 72 to open or close. By providing the valves 73a and 73b in such a manner, it is possible to easily switch between the first tank 71 and the second tank 72. In addition, when the three-way valve is used instead of the valves 73a and 73b, by controlling the three-way valve, it is possible to perform the same control as an opening and closing control of the valves 73a and 73b.

Based on the determination result, the controller 41 may be configured to be capable of controlling the valve (for example, the valve 73a) of the tank currently in use (for example, the first tank 71) to close. In addition, based on the determination result, the controller 41 may also be configured to be capable of controlling the valve of the tank in standby to open. For example, when the controller 41 determines that the remaining amount of the first tank 71 is insufficient based on the determination result by the determination processor 50, the controller 41 controls the valve 73b of the second tank 72 to open. The controller 41 (specifically, the process controller 51) independently controls the opening and closing of the valves 73a and 73b. Thereby, it is possible to easily manage the valves such as the valves 73a and 73b, and it is possible to ensure the control of the valves such as the valves 73a and 73b.

The controller 41 may be configured to be capable of controlling the processing of the wafer 31 to be continuously performed even while switching from the tank currently in use to the tank in standby. Even when switching between the first tank 71 and the second tank 72 occurs during the processing of the wafer 31, it is possible to continuously perform the substrate processing without being stopped. Since the controller 41 controls the tank switching independently from the substrate processing, it is possible to operate the substrate processing apparatus 100 without affecting the substrate processing.

The determination processor 50 may determine whether to perform the tank switching at a period in which a determination of whether to perform the tank switching can be appropriately performed, for example, at a period within a range from 0.1 second to 1 second. More preferably, the period is 0.1 second. For example, when the period is less than 0.1 second, the number of determinations by the determination processor 50 may increase, and a load on the substrate processing apparatus 100 may also increase. Thereby, the substrate processing may be affected. For example, when the period exceeds 1 second, a period for the determination of whether to perform the tank switching may become longer. Thereby, an accuracy of a tank switching timing may decrease. Thus, by performing the determination of whether to perform the tank switching at an appropriate period in such a manner, it is possible to reliably determine whether or not the tank needs to be switched.

In the present specification, a notation of a numerical range such as “from 0.1 second to 1 second” means that a lower limit and an upper limit thereof are included in the numerical range. Therefore, for example, the numerical range “from 0.1 second to 1 second” means a range equal to or higher than 0.1 second and equal to or lower than 1 second. The same also applies to other numerical ranges described herein.

The determination processor 50 may determine whether or not the tank needs to be switched at a start or an end of a recipe such as the process recipe. Thereby, it is possible to perform the tank switching without affecting the substrate processing.

The remaining amount may be calculated from a difference between an accumulated amount calculated by accumulating the flow rate of the source material per unit time (which is reported during the substrate processing) and a predefined volume of the source material in the tank. The controller 41 acquires a volume of the tank when the tank is replaced. For example, on a screen to which the notification processor 414 notifies, an item configured such that the tank volume can be input is provided. When the tank is replaced, the tank volume is input using the item. The determination processor 50 acquires the tank volume (which is input using the item) as the remaining amount, updates the remaining amount by subtracting the flow rate reported by a mass flow controller (MFC) (not shown), and compares the remaining amount (which is updated) with the threshold value. By clarifying the tank volume (tank capacity) in advance, it is possible to easily manage the remaining amount.

Each of the tanks may be provided with a pressure sensor configured to measure a pressure (inner pressure) of a tank related thereto. Then, the determination processor 50 may measure the remaining amount based on a pressure value measured by the pressure sensor provided in the tank currently in use, and may determine whether or not the tank currently in use needs to be switched based on the remaining amount measured as described above. For example, although not shown, the pressure sensor configured to measure the inner pressure of the tank related thereto is provided at an upper portion of the tank, the inner pressure of the tank is measured, and the remaining amount is measured from the inner pressure measured as described above. The threshold value may be a pressure instead of the remaining amount, and the inner pressure of the tank and the threshold value may be compared. By determining whether or not the tank needs to be switched based on the inner pressure of the tank, it is possible to perform the determination accurately.

Each of the tanks may be provided with a weight sensor (load cell) (not shown) configured to measure the weight of the tank related thereto. Then, the determination processor 50 may measure the remaining amount based on the weight measured by the weight sensor provided in the tank currently in use, and may determine whether or not the tank currently in use needs to be switched based on the remaining amount measured as described above. For example, the weight sensor is provided at a lower portion of the tank, and the weight of the tank is measured. By setting the threshold value to be the weight instead of the remaining amount, whether or not the tank needs to be switched is determined based on the weight. By determining whether or not the tank needs to be switched based on the weight of the tank, it is possible to perform the determination accurately.

After switching the tank, the controller 41 may issue a notification to replace the tank of which use is completed. When switching from the first tank 71 to the second tank 72, the first tank 71 needs to be replaced. Therefore, the controller 41 issues a notification indicating that the tank needs to be replaced. For example, a notification destination may be the notification processor 414, or may be an information terminal connected to the external communication interface 411 via the network, such as an email address of an administrator or a worker previously registered. By issuing the notification indicating that the tank needs to be replaced (that is, a notification requesting a tank replacement), the worker can recognize that the tank needs to be replaced.

The substrate processing apparatus 100 may further include the notification processor 414 configured to notify the processing status of the wafer 31. In addition, when receiving the notification from the controller 41, the notification processor 414 may issue the notification requesting to replace the tank currently in use. By issuing the notification (instruction) in a manner described above, the worker can recognize that the tank needs to be replaced.

According to the present embodiments, it is possible to obtain one or more effects mentioned above.

Hereinafter, an example of the substrate processing will be described. When a predetermined number of wafers 31 are charged (or loaded) into the boat 32 by a substrate transfer apparatus (not shown), a furnace opening shutter (not shown) is opened, and the lower end of the process furnace 29 (which has been closed by the furnace opening shutter) is opened. Subsequently, the boat 32 accommodating (or holding) a group of the wafers 31 is transferred (loaded) into the process furnace 29 by elevating the seal cap 35 by the boat elevator (not shown).

After the boat 32 is loaded, the wafers 31 loaded into the process furnace 29 are heated to a predetermined temperature by the heater 42. Then, a predetermined process such as a film forming process is performed on the wafers 31 using the gas such as the process gas supplied through the nozzle 56. After the wafers 31 are processed, the wafers 31 are discharged (unloaded) in an order reverse to that of loading the wafers 31.

When the substrate (that is, the wafers 31) are processed, the determination processor 50 checks the remaining amount in the tank currently in use (for example, the first tank 71), compares the remaining amount of the source material in the first tank 71 with the predetermined threshold value, checks whether or not the tank currently in use needs to be switched, and notifies the controller 41 when it is determined that the tank currently in use needs to be switched.

When the controller 41 receives the notification from the determination processor 50 and determines that the tank needs to be replaced, the controller 41 notifies the process controller 51 of the tank switching.

When receiving the notification from the controller 41, the process controller 51 performs a control to close the valve 73a installed between the first tank 71 currently in use and the buffer tank 74. In addition, the process controller 51 also performs a control to open the valve 73b installed between the second tank 72 (which is currently in standby) and the buffer tank 74.

When receiving the notification requesting the tank switching from the determination processor 50, the controller 41 performs a control for the notification processor 414 to issue a notification requesting the tank replacement.

When receiving the notification (indicating the necessity of the tank replacement) from the controller 41, the notification processor 414 notifies a message regarding the tank replacement.

### Substrate Processing Method

A substrate processing method according to the present embodiments may include:
processing the wafer 31;
(b) supplying the source material from the first tank 71 and the second tank 72 (that is, a plurality of tanks) configured to store the source material and further configured to be capable of being replaced;
(c) checking the remaining amount of the source material in the tank currently in use among the plurality of tanks during the substrate processing, and determining, from the remaining amount, whether or not the supply source of the source material needs to be switched from the tank currently in use to the tank in standby among the plurality of tanks; and
(d) controlling the supply of the source material to be continuously performed by switching the tank currently in use to the tank in standby based on a determination result obtained in (c).

### Method of Manufacturing Semiconductor Device

A method of manufacturing a semiconductor device according to the present embodiments may include:
(a) processing the wafer 31;
(b) supplying the source material from the first tank 71 and the second tank 72 (that is, the plurality of tanks) configured to store the source material and further configured to be capable of being replaced;
(c) periodically checking the remaining amount of the source material in the tank currently in use among the plurality of tanks during the substrate processing, and determining, from the remaining amount, whether or not the supply source of the source material needs to be switched from the tank currently in use to the tank in standby among the plurality of tanks; and
(d) controlling the supply of the source material to be continuously performed by switching the tank currently in use to the tank in standby based on a determination result in (c).

### Program

A program according to the present embodiments may cause the substrate processing apparatus 100, by a computer, to perform:
(a) processing the wafer 31;
(b) supplying the source material from the first tank 71 and the second tank 72 (that is, the plurality of tanks) configured to store the source material and further configured to be capable of being replaced;
(c) periodically checking the remaining amount of the source material in the tank currently in use among the plurality of tanks during the substrate processing, and determining, from the remaining amount, whether or not the supply source of the source material needs to be switched from the tank currently in use to the tank in standby among the plurality of tanks; and
(d) controlling the supply of the source material to be continuously performed by switching the tank currently in use to the tank in standby based on a determination result in (c).

### Other Embodiments of Present Disclosure

The technique of the present disclosure is described in detail by way of the embodiments mentioned above. However, the technique of the present disclosure is not limited thereto. The technique of the present disclosure may be modified in various ways without departing from the scope thereof.

In the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. Thus, in the present specification, the term “forming a predetermined layer (or a film) on a wafer” may refer to “forming a predetermined layer (or a film) directly on a surface of a wafer itself”, or may refer to “forming a predetermined layer (or a film) on a surface of another layer (or another film) formed on a wafer”. In the present specification, the terms “substrate” and “wafer” may be used as substantially the same meaning.

For example, the embodiments mentioned above are described by way of an example in which the film forming process for the semiconductor device is performed as the processing performed by the substrate processing apparatus. However, the technique of the present disclosure is not limited thereto. For example, the technique of the present disclosure may also be applied to an entirety of processes performed by exposing a vaporized gas to a substrate (on which a pattern with a high aspect ratio (that is, a pattern whose depth is greater than a width thereof) is formed. That is, in addition to or instead of the film forming process mentioned above, the technique of the present disclosure may also be applied to a process such as a process of forming an oxide film or a nitride film and a process of forming a film containing a metal element. For example, specific contents of the film forming process are not limited to those exemplified in the embodiments mentioned above. For example, in addition to or instead of the film forming process mentioned above, the technique of the present disclosure may be applied to other substrate processings such as an annealing process, an oxidation process, a nitridation process, a diffusion process and a lithography process.

In addition, for example, the technique of the present disclosure may also be applied to other substrate processing apparatuses such as an annealing apparatus, an oxidation apparatus, a nitridation apparatus, an exposure apparatus, a coating apparatus, a drying apparatus, a heating apparatus, an apparatus using plasma, and a combination thereof. That is, the technique of the present disclosure may also be applied when two or more substrate processing apparatuses mentioned above are provided together.

For example, the technique of the present disclosure may also be applied not only to a semiconductor manufacturing apparatus but also to an apparatus configured to process a glass substrate such as an LCD device. In addition, a type of the film is not particular limited. For example, the technique of the present disclosure may also be applied to a process of forming a film containing a substance such as a metal compound (such as W (Tungsten), Ti (Titanium) and Hf (Hafnium)) and a silicon compound (such as silicon nitride (SiN) and silicon (Si)). In addition, for example, the film forming process may include a process such as a CVD (Chemical Vapor Deposition) process, a PVD (Physical Vapor Deposition) process, the process of forming the oxide film or the nitride film and the process of forming the film containing the metal element.

For example, the embodiments mentioned above are described by way of an example in which a manufacturing process of the semiconductor device is performed. However, the technique of the present disclosure is not limited thereto. For example, the technique of the present disclosure may also be applied to various substrate processings such as a manufacturing process of a liquid crystal device, a manufacturing process of a solar cell, a manufacturing process of a light emitting device, a processing of a glass substrate, a processing of a ceramic substrate and a processing of a conductive substrate.

For example, the embodiments mentioned above are described by way of an example in which the tank is used as the storage. However, the technique of the present disclosure is not limited thereto. For example, the technique of the present disclosure may also be applied when a pipe capable of storing the gas is used instead of the tank.

In addition, the number of each component described in the present specification is not limited to one, and the number of each component may be two or more unless otherwise specified in the present specification.

For example, the embodiments mentioned above are described by way of an example in which a batch type substrate processing apparatus capable of simultaneously processing a plurality of substrates is used to form the film. However, the technique of the present disclosure is not limited thereto. For example, the technique of the present disclosure may also be preferably applied when a single wafer type substrate processing apparatus capable of processing one or several substrates at a time is used to form the film. In addition, the embodiments mentioned above are described by way of an example in which a substrate processing apparatus including a hot wall type process furnace is used to form the film. However, the technique of the present disclosure is not limited thereto. For example, the technique of the present disclosure may also be preferably applied when a substrate processing apparatus including a cold wall type process furnace is used to form the film.

Process procedures and process conditions of each process using the substrate processing apparatuses exemplified above may be substantially the same as those of the embodiments or modified examples mentioned above. Even in such a case, it is possible to obtain substantially the same effects as in the embodiments or the modified examples mentioned above.

In the present specification, the term “program” may refer to a program recorded on a non-transitory computer-readable recording medium, or may refer to a program product. In addition, the program may also be provided as the non-transitory computer-readable recording medium on which the program is recorded.

The technique of the present disclosure may also be applied when a constituent of one of the embodiments mentioned above is substituted with another constituent of another embodiment, or when a constituent of one of the embodiments mentioned above is added to another embodiment. In addition, the technique of the present disclosure may also be applied when the constituent of the embodiments mentioned above is omitted or substituted, or when a constituent is added to the embodiments mentioned above.

As described above, according to some embodiments of the present disclosure, it is possible to improve the productivity of the substrate processing.

What is claimed is:

1. A substrate processing apparatus comprising:
a process chamber in which a substrate is processed;
a source material supplier configured to supply a source material to the process chamber and provided with a plurality of containers, wherein the plurality of containers are configured to store the source material and configured to be capable of being replaced;
a determination processor configured to check a remaining amount of the source material in a container currently in use among the plurality of containers during a substrate processing, and further configured to determine, from the remaining amount, whether or not a supply source of the source material needs to be switched from the container currently in use to a container in standby among the plurality of containers; and
a controller configured to be capable of controlling //the source material supplier such that supply of the source material is continuously performed by switching the container currently in use to the container in standby based on a determination result obtained by the determination processor.

2. The substrate processing apparatus of claim 1, wherein the determination processor is further configured to compare the remaining amount in the container currently in use with a predetermined threshold value and further configured to determine whether or not the container currently in use needs to be switched.

3. The substrate processing apparatus of claim 2, wherein the determination processor is further configured to notify the controller of the determination result that the container currently in use needs to be switched to the container in standby when the remaining amount in the container currently in use is less than the predetermined threshold value.

4. The substrate processing apparatus of claim 2, wherein the determination processor is further configured to notify the controller of the determination result that the container currently in use does not need to be switched when the remaining amount in the container currently in use is greater than or equal to the predetermined threshold value.

5. The substrate processing apparatus of claim 2, wherein the determination processor is further configured not to notify the controller of the determination result that the container currently in use does not need to be switched when the remaining amount in the container currently in use is greater than or equal to the predetermined threshold value.

6. The substrate processing apparatus of claim 1, further comprising:
a plurality of valves provided in a plurality of supply pipes installed between the source material supplier and the process chamber, wherein each of the plurality of valves is configured to perform the supply of the source material from the plurality of containers to the process chamber and configured to stop the supply of the source material from the plurality of containers to the process chamber,
wherein the controller is further configured to be capable of controlling each of the plurality of valves to open or close based on the determination result.

7. The substrate processing apparatus of claim 6, wherein the controller is further configured to be capable of controlling a valve, among the plurality of valves, provided at the container currently in use to close based on the determination result.

8. The substrate processing apparatus of claim 6, wherein the controller is further configured to be capable of controlling a valve, among the plurality of valves, provided at the container in standby to open based on the determination result.

9. The substrate processing apparatus of claim 1, wherein the controller is further configured to be capable of controlling the substrate processing to be continuously performed even while switching from the container currently in use to the container in standby.

10. The substrate processing apparatus of claim 1, wherein the determination processor is further configured to determine whether to perform a container switching at a period that makes it possible to appropriately perform a determination on whether or not the container needs to be switched.

11. The substrate processing apparatus of claim 1, wherein the determination processor is further configured to determine whether or not the container needs to be switched at a start or an end of a recipe of the substrate processing.

12. The substrate processing apparatus of claim 1, wherein the remaining amount is calculated from a difference between an accumulated amount calculated by accumulating a flow rate of the source material per unit time reported during the substrate processing and a predefined volume of the source material in the container.

13. The substrate processing apparatus of claim 1, further comprising:
a plurality of pressure sensors configured to measure inner pressures of the plurality of containers, respectively,
wherein the determination processor is further configured to measure the remaining amount based on a pressure value measured by a pressure sensor, among the plurality of pressure sensors, provided at the container currently in use, and further configured to determine whether or not the container currently in use needs to be switched from the remaining amount measured based on the pressure value.

14. The substrate processing apparatus of claim 1, further comprising:
a plurality of weight sensors configured to measure weights of the plurality of containers, respectively,
wherein the determination processor is further configured to measure the remaining amount based on a weight measured by a weight sensor, among the plurality of weight sensors, provided at the container currently in use, and further configured to determine whether or not the container currently in use needs to be switched from the remaining amount measured based on the weight.

15. The substrate processing apparatus of claim 1, wherein the controller is further configured to be capable of, after switching the container, issuing a notification to replace the container of which use is completed.

16. The substrate processing apparatus of claim 15, further comprising:
a notification processor configured to notify a processing status of the substrate,
wherein the notification processor is further configured to issue a notification to replace the container currently in use when receiving such notification from the controller.

17. The substrate processing apparatus of claim 1, further comprising:
a storage provided between the process chamber and the plurality of containers and configured to temporarily accumulate the source material,
wherein the storage is further configured to be capable of supplying the source material to the process chamber even while switching from the container currently in use to the container in standby.

18. A substrate processing method comprising:
(a) processing a substrate;
(b) supplying a source material from a plurality of containers configured to store the source material and further configured to be capable of being replaced;
(c) checking a remaining amount of the source material in a container currently in use among the plurality of containers during a substrate processing, and determining, from the remaining amount, whether or not a supply source of the source material needs to be switched from the container currently in use to a container in standby among the plurality of containers; and
(d) controlling the supplying of the source material to be continuously performed by switching the container currently in use to the container in standby based on a determination result in (c).

19. A method of manufacturing a semiconductor device, comprising:
the method of claim 18.

20. A non-transitory computer-readable recording medium storing a program that causes a substrate processing apparatus, by a computer, to perform:
(a) processing a substrate;
(b) supplying a source material from a plurality of containers configured to store the source material and further configured to be capable of being replaced;
(c) periodically checking a remaining amount of the source material in a container currently in use among the plurality of containers during a substrate processing, and determining, from the remaining amount, whether or not a supply source of the source material needs to be switched from the container currently in use to a container in standby among the plurality of containers; and
(d) controlling the supplying of the source material to be continuously performed by switching the container currently in use to the container in standby based on a determination result in (c).
